(19) United States
(12) Patent Application Publication
(10) Pub. No.: US 2026/0190949 A1
(43) Pub. Date: Jul. 2, 2026

(54) HOLDING MODULE, APPARATUS HAVING THE SAME, AND A METHOD OF USING THE SAME

(71) Applicant: Taiwan Semiconductor Manufacturing Company, Ltd., Hsinchu (TW)

(72) Inventors: Yen-Hsiang Chen, New Taipei City (TW); Hung-Chih Wang, Hsinchu (TW); Chih-Wei CHOU, Hsinchu (TW); Yuan-Hsin Chi, Taichung City (TW); Sheng-Yuan Lin, Hsinchu (TW)

(73) Assignee: Taiwan Semiconductor Manufacturing Company, Ltd., Hsinchu (TW)

(21) Appl. No.: 19/002,628

(22) Filed: Dec. 26, 2024

(51) Int. Cl. H01L 21/687; C23C 14/50; H01J 37/32

(52) U.S. Cl. CPC H10P 72/7624; C23C 14/50; H01J 37/32642; H01J 37/32715; H01J 2237/2007; H01J 2237/332

(57) ABSTRACT

A holding module of a substrate includes a cover and a ring structure. The cover includes a body portion having a step-form profile and a horizontal extending portion connecting to an edge of the body portion. The ring structure is removably installed to the horizontal extending portion, and includes a supporting structure and a cap. The supporting structure stands on the horizontal extending portion. The cap is disposed on the supporting structure, where the supporting structure is disposed between the cover and the cap. The cover and ring structure constitute an accommodating space for the substrate, and the substrate is laid on the body portion and is free from the ring structure.

### BACKGROUND

Manufacturing a semiconductor integrated circuit (IC) typically involves numerous processing techniques that require elevated wafer temperatures to perform the desired processes, such as chemical vapor deposition (CVD), physical vapor deposition (PVD), dry etching, or other processing techniques. Due to the raising temperature, severe bowing or warping may likely occur, which leads to damages in the processing wafers. Therefore, the improved wafer holding apparatuses are key factors for suppressing such impacts.

### BRIEF DESCRIPTION OF THE DRAWINGS

Aspects of the disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic cross-sectional view of an apparatus having a holding module in accordance with some embodiments of the disclosure.

FIG. 2 is a schematic, cross-sectional view showing a configuration of the holding module included in the apparatus depicted in FIG. 1.

FIG. 3 is a schematic plane view showing a configuration of the holding module included in the apparatus depicted in FIG. 1.

FIG. 4 is a schematic, enlarged cross-sectional view showing a configuration of a portion of the holding module included in the apparatus depicted in FIG. 1.

FIG. 5 is a schematic plane view showing a configuration of a holding module in accordance with some alternative embodiments of the disclosure.

FIG. 6 is a schematic, enlarged cross-sectional view showing a configuration of a portion of the holding module depicted in FIG. 5.

FIG. 7 is a schematic plane view showing a configuration of a holding module in accordance with some alternative embodiments of the disclosure.

FIG. 8 is a schematic, enlarged cross-sectional view showing a configuration of a portion of the holding module depicted in FIG. 7.

FIG. 9 through FIG. 12 are schematic, enlarged cross-sectional views respectively showing various embodiments of a configuration of a portion of a holding module in accordance with some embodiments of the disclosure.

FIG. 13 is a flowchart of a method for using an apparatus in accordance with some embodiments of the disclosure.

### DETAILED DESCRIPTION

The following disclosure provides many different embodiments, or examples, for implementing different features of the provided subject matter. Specific examples of components, values, operations, materials, arrangements, or the like, are described below to simplify the disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first”, “second”, “third”, “fourth”, “fifth”, “sixth”, “seventh”, and the like, may be used herein for ease of description to describe similar or different element(s) or feature(s) as illustrated in the figures, and may be used interchangeably depending on the order of the presence or the contexts of the description.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

It should be appreciated that the following embodiment(s) of the disclosure provides applicable concepts that can be embodied in a wide variety of specific contexts. The embodiments are intended to provide further explanations but are not used to limit the scope of the disclosure. The specific embodiment(s) described herein is related to an apparatus (such as a processing apparatus for a process(es) involving elevated substrate temperature, such as chemical vapor deposition (also referred as CVD), physical vapor deposition (also referred as PVD), atomic layer deposition (also referred as ALD), impurity doping, rapid thermal process (also referred as RTP), anneal, and metal deposition), where the apparatus includes a holding module to support and retain a substrate during the processing. In some embodiments of the disclosure, the holding module includes a cover and a cover ring standing on the peripherical region of the cover, where the cover and the cover ring confine an accommodating space for a placement of the substrate, and the substrate is placed on the cover and surrounding by the cover ring, and the accommodating space is spatially communicated with the processing region or plasma zone through an opening formed in and penetrating through the cover ring. In accordance with some embodiments of the disclosure, due to the opening formed in and penetrating through the cover ring accessibly exposes the substrate, and the substrate is free from (e.g., not in physical contact with) the cover ring, the holding module is considered a self-aligned and non-contact holding module, thereby suppressing the broken or crack issue due to the pressure concentrated at certain spots of the bowing or warping substrate. In accordance with some embodiments of the disclosure, due to the cover has a step-shaped (or step-form) profile with a thickness increasing from a center of the cover to an edge thereof and a width decreasing from the center to the edge, more contact points (or areas) between the substrate and the cover are arrived, which allows more uniform heat conduction onto the substrate, thereby enhancing heat uniformity on the substrate (e.g., a warped wafer).

In the disclosure, it should be appreciated that the illustration of components throughout all figures is schematic and is not in scale. The method may be part of a wafer level packaging process. It is understood that additional processes may be provided before, during, and after the illustrated method, and that some other processes may only be briefly described herein. Throughout the various views and illustrative embodiments of the disclosure, the elements similar to or substantially the same as the elements described previously will use the same reference numbers, and certain details or descriptions (e.g., the materials, formation processes, positioning configurations, electrical connections, etc.) of the same elements would not be repeated. For clarity of illustrations, the drawings are illustrated with orthogonal axes (X, Y and Z) of a Cartesian coordinate system according to which the views are oriented; however, the disclosure is not specifically limited thereto.

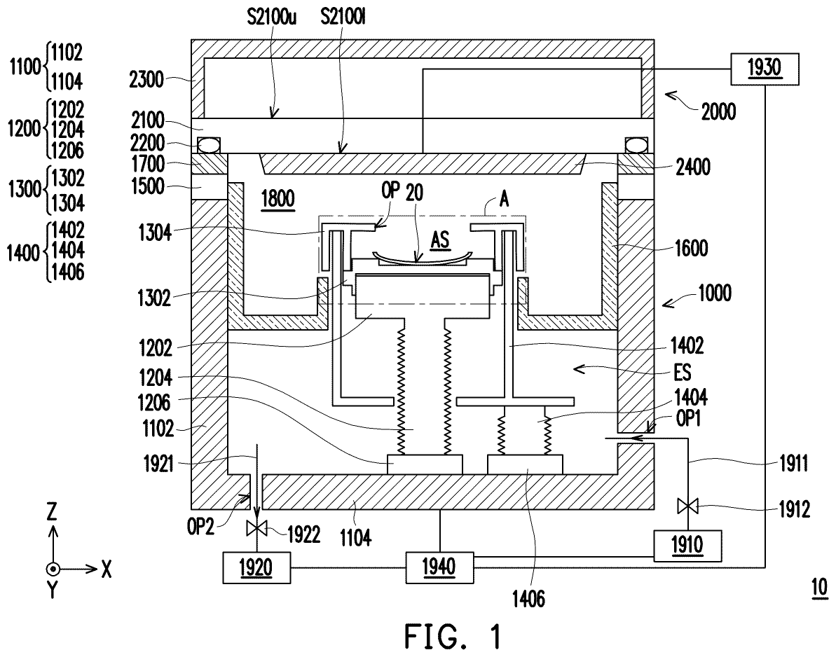

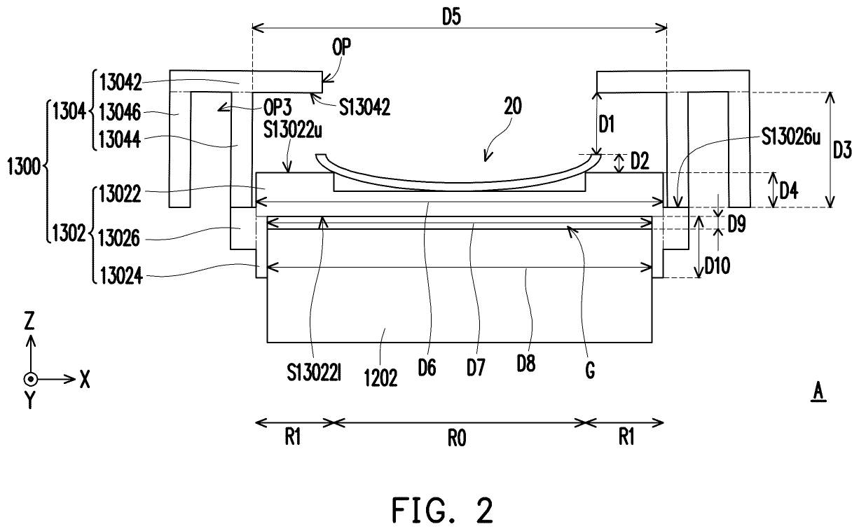

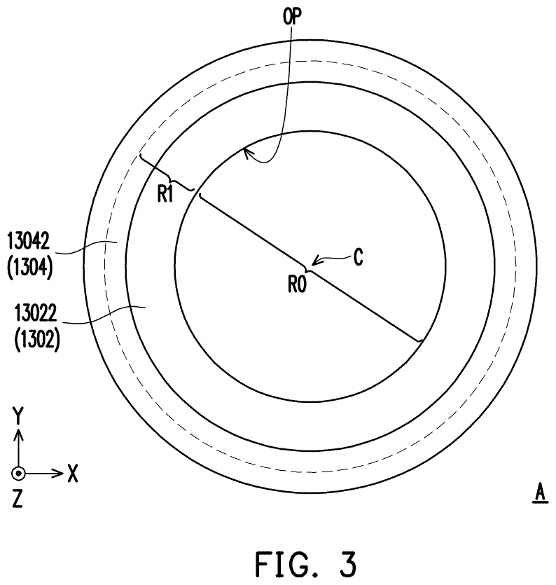

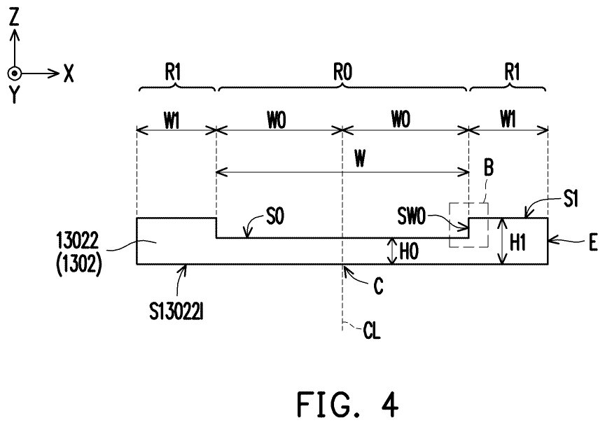

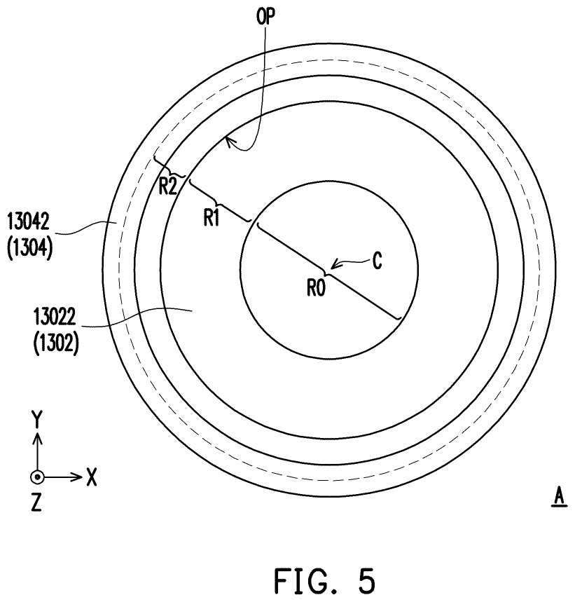

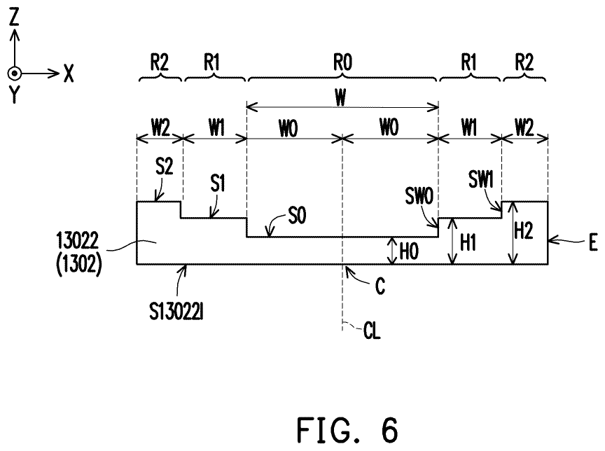

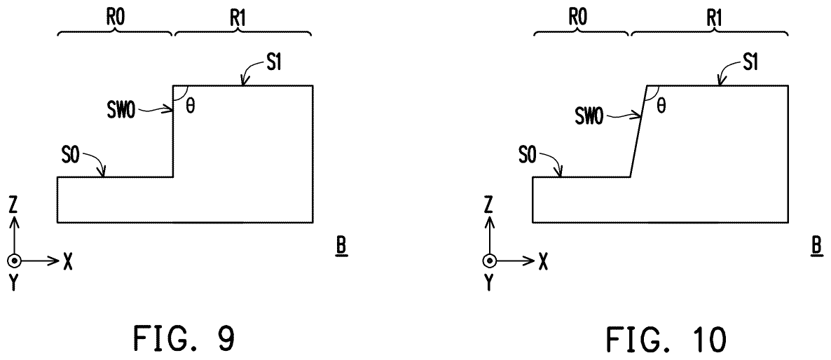

FIG. 1 is a schematic cross-sectional view of an apparatus (e.g., 10) having a holding module (e.g., 1300) in accordance with some embodiments of the disclosure. FIG. 2 is a schematic, cross-sectional view showing a configuration of the holding module (e.g., 1300) included in the apparatus (e.g., 10) depicted in FIG. 1, which are outlined by a dashed-box A depicted in FIG. 1. FIG. 3 is a schematic plane view showing a configuration of the holding module (e.g., 1300) included in the apparatus depicted in FIG. 1. FIG. 4 is a schematic, enlarged cross-sectional view showing a configuration of a portion (e.g., 13022) of the holding module (e.g., 1300) included in the apparatus (e.g., 10) depicted in FIG. 1. FIG. 6 is a schematic, enlarged cross-sectional view showing a configuration of a portion of the holding module depicted in FIG. 5. FIG. 9 through FIG. 12 are schematic, enlarged cross-sectional views respectively showing various embodiments of a configuration of a portion of a holding module in accordance with some embodiments of the disclosure, which are outlined by a dashed-box B depicted in FIG. 4. The embodiments are intended to provide further explanations, but are not used to limit the scope of the disclosure.

Referring to FIG. 1, in some embodiments, an apparatus 10 is provided. As shown in FIG. 1, the apparatus 10 includes a lower process assembly 1000 and an upper process assembly 2000 physically coupled to (e.g., disposed on) the lower process assembly 1000, and an enclosure space ES (or referred to as a processing space) is confined by the lower process assembly 1000 and the upper process assembly 2000. For example, the lower process assembly 2000 includes a chamber 1100, a pedestal assembly 1200, a holding module 1300, a lift assembly 1400, an adapter 1500, an insulator 1600 and a shield 1700, as shown in FIG. 1. In some embodiments, the chamber 1100 includes sidewalls 1102 and a bottom 1104, where the sidewalls 1102 connects to (e.g., in physically contact with) a periphery of the bottom 1104. The sidewalls 1102 and the bottom 1104 of the chamber 1100 independently may be fabricated by machining and welding plates of stainless steel or by machining a single mass of aluminum. However, the disclosure is not limited thereto, alternatively, the sidewalls 1102 include or are plated with aluminum and the bottom 1104 includes or is plated with stainless steel, or vice versa. The sidewalls 1102 may contain a slit valve (not shown) to provide for entry and egress of a substrate 20 from the chamber 1100 of the apparatus 10, to facilitate transportation of the substrate 20 with a substrate transfer mechanism disposed exterior to the chamber 1100, such as a single blade robot. The chamber 1100 may be referred to as a housing of the apparatus 10.

In some embodiments, the substrate 20 is a doped or undoped silicon wafer or an active layer of a semiconductor-on-insulator (SOI) substrate. In an alternative embodiment, the substrate 20 may be a silicon germanium, however the disclosure is not limited thereto. The substrate 20 may, for example, include other semiconductor material, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. In some embodiment, the substrate 20 may be as multi-layered or gradient substrates. In one embodiment, the substrate 20 may be a substrate used in the semiconductor device manufacturing industry or used in industries other than semiconductor manufacturing, the disclosure is not limited thereto. For example, as shown in FIG. 1, the substrate 20 is a wafer substrate including a silicon substrate deposited with a GaN layer thereon. The disclosure is not limited the type and/size of the substrate 20, as long as the substrate 20 is a warped substrate.

In some embodiments, at least one of the sidewalls 1102 or the bottom 1104 includes one or more inlet/outlet ports for entry and exhaust process gases(es), carrier gas(es) and/or cleaning gas(es). For example, the apparatus 10 further includes one or more gas sources and one or more exhaust pumps. As shown in FIG. 1, the sidewall 1102 has an one inlet/outlet port OP1 to allow a gas source 1910 providing a carrier gas to the chamber 1100 via a conduit 1911 and a valve 1912, during the processing. The gas source 1910 includes a non-reactive gas such as argon or xenon, which is capable of energetically impinging upon and sputtering material from the target (e.g., 2400). In addition to or alternatively, the gas source 1910 may include a reactive gas, such as one or more of an oxygen-containing gas, a nitrogen-containing gas, a methane-containing gas or fluorine-containing gas, that reacts with the sputtering material to form a layer on the substrate 20, if needed. Sometimes, the gas (either non-reactive or reactive) provided by the gas sources is referred to as a process gas. Additionally, the sidewall 1102 may include additional one or more inlet/outlet ports (not shown) to allow another gas source (not shown) providing a cleaning gas to the chamber 1100 via another conduit (not shown) and another valve (not shown), after the processing. The cleaning gas may include a gas, such as ammonia, trimethylgallium, or purified gases, that help maintain the purity of the deposition environment, without introducing contamination.

Spent process gas and byproducts may be exhausted from the chamber 1100 through an inlet/outlet port OP2 that receive spent process gas and direct the spent process gas to an exhaust conduit 1921 having an adjustable position gate valve 1922 to control the pressure inside the chamber 1100. The exhaust conduit 1921 is connected to one or more exhaust pumps 1920. The pressure of the sputtering gas in the chamber 1100 may be set to sub-atmospheric levels, such as a vacuum environment, for example, a pressure of about 0.6 mTorr to about 400 mTorr. A plasma is formed from the sputtering gas between the substrate 20 and the target (e.g., 2400). Ions within the plasma are accelerated toward the target (e.g., 2400) and cause material to become dislodged from the target (e.g., 2400). The dislodged target material is deposited on the substrate 20.

In some embodiments, a pedestal assembly 1200 is supported from the bottom 1104 of the chamber 1100. The pedestal assembly 1120 supports the holding module 1300 along with the substrate 20 during processing. The pedestal assembly 1200 includes a stage 1202, a bellow 1204 and a lift mechanism 1206. The pedestal assembly 1200 is coupled to the bottom 1104 of the chamber 1100 by the lift mechanism 1206 that is configured to raise and lower the stage 1202 between an upper processing position (e.g., during deposition of target material on the substrate 20) and a lower transfer position (e.g., where the substrate 20 is transferred onto or away from the pedestal assembly 1200). A bellows 124 is disposed between the stage 1202 and the lift mechanism 1206 to isolate the interior of the pedestal assembly 1200 to the exterior of the pedestal assembly 1200. For example, the stage 1202 includes a ceramic, a metal or a combination thereof, such as aluminum silicon carbide, which provides improved strength and durability than ceramic and also has improved heat transfer properties. However the disclosure is not limited thereto. In certain embodiments, the stage 1202, for example, serves not only as a support element for holding a positioning location of the substrate 20 but also as a heating element for heating the substrate 20. In certain embodiments, one or more than one heating devices (not shown) are embedded in and coupled to the stage 1202, where the substrate may be heated to a predetermined temperature (e.g. 300° C.˜400° C.) during the deposition process. The number and type of the heating device are not limited in the disclosure, and may be designated based on the demand. In addition, a cooling plate/device may be disposed within stage 1202 to thermally regulate the substrate 20. The number and type of the cooling plate/device are not limited in the disclosure, and may be designated based on the demand. In the above embodiments, the lift mechanism 1206 is disposed inside the chamber 1100, however, the disclosure is not limited thereto; alternatively, the lift mechanism 1206 may be located outside the chamber 1100 and coupled to the bottom 1104 of the chamber 1100, where the bellow 1204 may be sealably connect to the stage 1202, the lift mechanism 1206 and the bottom 1104 of the chamber 1100. In some embodiments, the stage 1202 is referred to as a heater or a thermal controller.

In some embodiments, the holding module 1300 is disposed on the pedestal assembly 1200, where the holding module 1300 is capped onto a top portion of the pedestal assembly 1200 with a gap G, as shown in FIG. 1 and FIG. 2. For example, during the processing, the gap G is filled with a backside gas to facilitate the uniformity of heat conduction during the processing. For example, the backside gas includes Ar. In some embodiment, the backside gas is heated by the stage 1202 during the processing, where due to the backside gas evenly distributed inside the gap G, the holding module 1300 above the gap G is also well-heated, and the heat uniformity thereof is ensured. In a non-limiting example, the process gas provided by the gas source 1910 can be the same as the backside gas. In another non-limiting example, the process gas provided by the gas source 1910 can be different from the backside gas. In some embodiments, the holding module 1300 includes a cover 1302 and a cover ring 1304 is free standing on (e.g., removably installed onto) the periphery of the cover 1302. As shown in FIG. 1 and FIG. 2, the cover 1302 includes a body portion 13022 having a surface S13022u and a surface 13022l opposite to the surface S13022u along the direction Z, a vertical extending portion 13024 attached to the surface S13022l and extending toward to the stage 1202 along the direction Z, and a horizontal extending portion 13026 attached to the outer edges of the body portion 13022 and the outer edges of the vertical extending portion 13024 and extending toward to away therefrom along the directions X and Y. In other words, if considering a plane view (e.g., a XY plane), the vertical extending portion 13024 and the horizontal extending portion 13026 may independently include a ring shape, and the body portion 13022 may include a circular or elliptical shape. However, the shape of the holding module 1300 corresponds to the shape of the stage 1202 of the pedestal assembly 1200, the disclosure is not limited thereto. Continued on FIG. 1 and FIG. 2, in some embodiments, the holding module 1300 is secured onto the stage 1202 of the pedestal assembly 1200 with the gap between the body portion 13022 and the stage 1202 by fixing the vertical extending portion to the stage 1202 via a fastener(s) (e.g., blots or blots threaded with nuts, with or without washer).

In one embodiment, the body portion 13022, the vertical extending portion 13024 and the horizontal extending portion 13026 may be integrally formed, however the disclosure is not limited thereto. In the embodiments, for a clear illustration purpose, an interface of two elements or portions connected to each other may be indicated by a dotted line; or an element or portion may be divided into two or more different sections by one or more than one dotted lines. In an alternative embodiment, the body portion 13022, the vertical extending portion 13024 and the horizontal extending portion 13026 may be formed individually and then be mechanically assembled to each other.

The body portion 13022 of the cover 1302 may has a step-form profile, as shown in FIG. 1 through FIG. 4. In some embodiments, in the direction Z, a cross-section of the cover 1302 has a step-form profile, where a step number (n) is greater than or equal to one. If considering n=1, the cover 1302 includes two regions, a region R0 (e.g., R(n−1)) and a region R1 (e.g., R(n)), and the region R1 surrounds and connects to the region R0, for example, see FIG. 3. As shown in FIG. 4, for example, the region R0 has a width W and a height H0, and the region R1 with a width W1 and a height H1, where the width W is greater than the width W1, and the height H1 is greater than the height H0. In some embodiments, as shown in FIG. 4, the center of the body portion 13022 is located at the region R0, where a central line CL is denoted for indicating a location of the center of the body portion 13022, and the body portion 13022 of the cover 1302 is point symmetric. In addition, the cover 1302, as a whole, may be point symmetric. In other words, the width W of the region R0 is two times a width W0 between the center of the body portion 13022 and the edge of the region R0 (e.g., W=2*W0). In some embodiments, the width W0 is greater than the width W1. In some embodiments, the widths of the regions of the cover 1302 is decreased from the center (denoted as “C” in FIG. 4) of the cover 1302 toward to the edge (denoted as “E” in FIG. 4) of the cover 1302, which enhances the heat transportation. In some embodiments, the heights of the regions of the cover 1302 is increased from the center (denoted as “C” in FIG. 4) of the cover 1302 toward to the edge (denoted as “E” in FIG. 4) of the cover 1302, where the heights of each region of the cover 1302 is greater than or substantially equal to 0.5 mm, thereby maintaining the strength of the body portion 13022 and avoiding fracture.

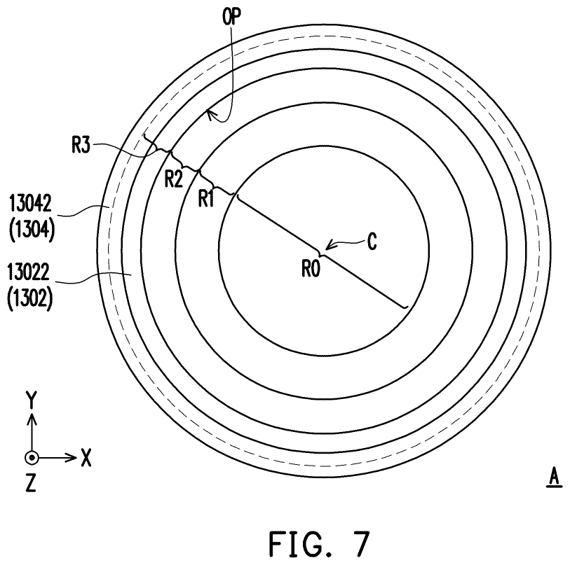

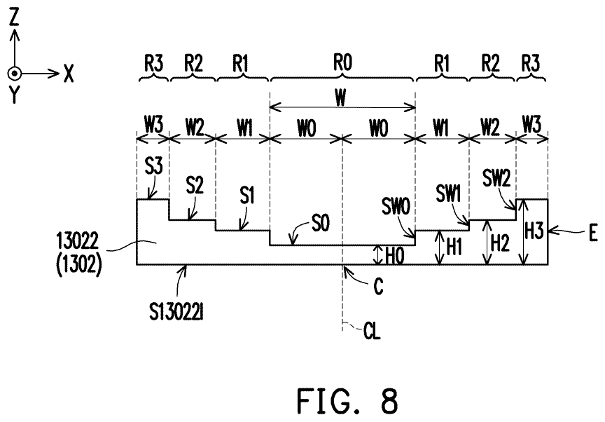

In some embodiments, the step number (n) of the profile of the body portion 13022 is greater than 1, see FIG. 5 and FIG. 6 and/or FIG. 7 and FIG. 8. Referring to FIG. 5 and FIG. 6, in a non-limiting example, if considering n=2, the cover 1302 includes three regions, a region R0 (e.g., R(n−2)), a region R1 (e.g., R(n−1)), and a region R2 (e.g., R(n)), where the region R2 surrounds and connects to the region R1, and the region R1 surrounds and connects to the region R0, for example, see FIG. 5. As shown in FIG. 6, for example, the region R0 has a width W (which equals to 2*W0) and a height H0, the region R1 with a width W1 and a height H1, and the region R2 with a width W2 and a height H2, where the width W is greater than the widths W1, W2, the width W1 is greater than the width W2, the heights H1 and H2 are greater than the height H0, and the height H2 is greater than the height H1. In some embodiments, the width W0 is greater than the widths W1, W2. Referring to FIG. 7 and FIG. 8, in another non−limiting example, if considering n=3, the cover 1302 includes three regions, a region R0 (e.g., R(n−3)), a region R1 (e.g., R(n−2)), a region R2 (e.g., R(n−1)) and a region R3 (e.g., R(n)), where the region R3 surrounds and connects to the region R2, the region R2 surrounds and connects to the region R1, and the region R1 surrounds and connects to the region R0, for example, see FIG. 7. As shown in FIG. 8, for example, the region R0 has a width W (which equals to 2*W0) and a height H0, the region R1 with a width W1 and a height H1, the region R2 with a width W2 and a height H2, and the region R3 with a width W3 and a height H3, where the width W is greater than the widths W1, W2 and W3, the width W1 is greater than the widths W2 and W3, and the width W2 is greater than the width W1, while the heights H1, H2 and H3 are greater than the height H0, the heights H2 and H3 are greater than the height H1, and the height H3 is greater than the height H2. In some embodiments, the width W0 is greater than the widths W1, W2 and W3. In another non−limiting example (no shown), if considering n approaches infinite, the cover 1302 includes numerous regions (e.g., n regions), e.g., R0, R1, R2, R3, R4, R5, R6, R7, R10, . . . , and Rn, the profile of the body portion 13022 would mostly reach to a concave shape which likely match to the warpage of the substrate 20. Due to the step number (n) of the profile of the body portion 13022 is greater than or equal to one, the contact area between the substrate 20 and the cover 1302 of the holding module 1300 will be increased. In the disclosure, more step number the body portion 13022 obtained, the more contact area between the substrate 20 and the cover 1302 of the holding module 1300 is achieved, thereby enhancing the heat uniformity of the substrate during the processing. In other words, the step-form profile of the body portion 13022 matches a warpage of the substrate 20.

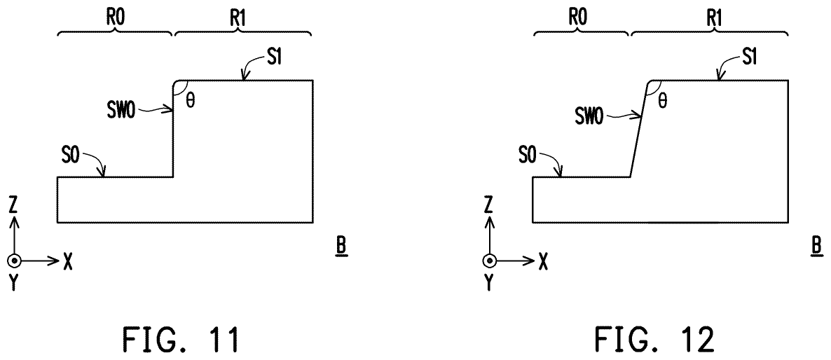

In some embodiments, back to FIG. 1 through FIG. 4 in conjunction with FIG. 9, the region R0 of the body portion 13022 has a surface S0 extending along the X-Y plane, a bottom surface (not labeled) opposite to the surface S0, a sidewall SW0 connecting the edge of the surface S0 and extending upwards, and the region R1 of the body portion 13022 has a surface S1 and a bottom surface (not labeled) opposite to the surface S1, where the bottom surfaces of the regions R1 and R0 are substantially coplanar to and level with each other, which constitute the surface S13022l. As shown in FIG. 4 and FIG. 9, the sidewall SW0 of the region R0 connects the surface S0 and the surface S1, where an included angle θ confined by the sidewall SW0 and the surface S1 is 90 degrees, for example. In other words, the sidewall SW0 is a vertical sidewall. However, the disclosure is not limited thereto, alternatively, the included angle θ confined by the sidewall SW0 and the surface S1 greater than 90 degrees and less than 180 degrees, where the sidewall SW0 is a slant sidewall, see FIG. 10. In the above embodiment, the sidewall SW0 and the surface S1 are intersected and connected to form a sharp tip, see FIG. 9 and FIG. 10. However, the disclosure is not limited thereto, the sidewall SW0 and the surface S1 may be intersected and connected to form a rounded tip, see FIG. 11 and FIG. 12. The configurations discussed in FIG. 9 through FIG. 12 may independently or combinedly adopted by the body portion 13022 of the cover 1302, in part or all, regardless the step number of the profile of the body portion 13022; as long as the step number of the profile of the body portion 13022 is greater than or equal to one. The disclosure is not limited thereto.

As illustrated in FIG. 1 and FIG. 2, the cover ring 1304 is removably placed onto the cover 1302 (e.g., the horizontal extending portion 13026) to form an accommodating space AS for the substrate 20, for example. In some embodiments, the cover ring 1304 includes supporting structure 13044, 13046 and a cap 13042 disposed on and connecting to the supporting structure 13044, 13046, where the supporting structure 13044 is free standing on (e.g., removably placed onto) a surface S13026u of the horizontal extending portion 13026. As shown in FIG. 1, for example, a gap OP3 confined by the cap 13042 and the supporting structure 13044, 13046, where the lift assembly 1400 is inserted into the gap OP3 and further in contact with the cap 13042 which allows raisings or lowering the position of the cover ring 1304 for the entry and egress of the substrate 20 from the holding module 1300, so to facilitate transportation of the substrate 20 with a substrate transfer mechanism disposed exterior to the chamber 1100, such as a single blade robot. In some embodiments, the lift assembly 1400 includes a supporting structure 1402, a bellows 1404 and a lift mechanism 1406, where the lift assembly 1400 is coupled to the bottom 1104 of the chamber 1100 by the lift mechanism 1406 that is configured to raise and lower the supporting structure 1402 between an opening position (e.g., where the substrate 20 is transferred onto or removed from the holding module 1300) and a enclosing position (e.g.,, during deposition of target material on the substrate 20) for the cover ring 1304. For example, as the substrate 20 is transferred onto the cover 1302 or removed from the cover 1302, the supporting structure 1402 is at the opening position (that the cover ring 1304 is lifted up from and spacing apart from the surface S13026u of the horizontal extending portion 13026 of the cover 1302 by the supporting structure 1402 of the lift mechanism 1400) and the stage 1202 is at the lower transfer position (that the stage 1202 is lowered downward from and spacing apart from the target (e.g., 2400) by the lift mechanism 1206), which allows transferring the substrate into and/or out of the holding module 1300.

For example, during the processing, the supporting structure 1402 is at the enclosing position (that the cover ring 1304 is lowered downward from and in contact with the surface S13026u of the horizontal extending portion 13026 of the cover 1302 by the supporting structure 1402 of the lift mechanism 1400) and the stage 1202 is at the upper transfer position (that the stage 1202 is lifted up and closer to the target (e.g., 2400) by the lift mechanism 1206), which allows maintains and retains the location of the substrate 20 during the process. A bellow 1404 is inside the chamber 1100 and disposed between the supporting structure 1402 and the lift mechanism 1406 to isolate the interior of the lift assembly 1400 to the exterior of the lift assembly 1400. In the above embodiments, the lift mechanism 1406 is disposed inside the chamber 1100, however, the disclosure is not limited thereto; alternatively, the lift mechanism 1406 may be located outside the chamber 1100 and coupled to the bottom 1104 of the chamber 1100, where the bellow 1404 may be sealably connect to the supporting structure 1402, the lift mechanism 1406 and the bottom 1104 of the chamber 1100.

As shown in FIG. 1 through FIG. 4, in some embodiments, the cover ring 1304 has an opening OP formed in the cap 13042, where the opening OP penetrates the cap and so spatially communicates the enclosure space ES (e.g., confined by the upper process assembly 2000 and the lower process assembly 1000) and the accommodating space AS inside the holding module 1300, and the substrate 20 is accessibly exposed by the opening OP and under the target (e.g., 2400) during the processing. Due to the configuration of the cover ring 1304 of the holding module 1300, the holding module 1300 is considered a self-aligned holding module. Continued on FIG. 2, the substrate 20 is not in contact with (e.g., no physical contact with) the cover ring 1304 of the holding module 1300, which suppresses the possibility of the broken or crack issue due to the pressure concentrated at certain spots of the bowing or warping substrate in the thermal treatment.

In some embodiments, a distance D1 is between a highest point of the substrate 20 to the cap 13042 (e.g., a surface S13042) of the cover ring 1304, a distance D2 is between the highest point of the substrate 20 to the body portion 13022 (e.g., the surface S13022u) of the cover 1302, as shown in FIG. 2. For example, the distance D1 is not zero. In a non-limiting example, the distance D1 is greater than or substantially equal to the 0.01 mm. In some embodiment, the supporting structure 13044 has a thickness D3. For example, the thickness D3 is not zero. In a non-limiting example, the thickness D3 is substantially equal to a sum of the distance D1 and the distance D2. In some embodiments, a distance D4 is between the surface S13022u of the body portion 13022 and the surface S13026u of the horizontal extending portion 13026, where D3-D4>D2. Due to the configuration of the cover ring 1304 of the holding module 1300 in relative to the substrate 20, the holding module 1300 is further considered a non-contact holding module. In some embodiments, an inner diameter D5 of the supporting structure 13044 of the cover ring 1304 is greater than a width D6 of the body portion 13022 of the cover 1302 for ensuring the placement of the cover ring 1304 over the cover 1302, as shown in FIG. 2. In some embodiments, an inner diameter D7 of the vertical extending portion 13024 of the cover 1302 is greater than or substantially equal to a width D8 of the stage 1202 of the pedestal assembly 1200 for ensuring the placement of the holding module 1300 over the pedestal assembly 1200. In a non-limiting example, the inner diameter D7 of the vertical extending portion 13024 of the cover 1302 is greater than the width D8 of the stage 1202 of the pedestal assembly 1200. In some embodiments, the gap G has a thickness D9, and the vertical extending portion 13024 has a thickness D10, where the thickness D10 of the vertical extending portion 13024 is greater than the thickness D9 of the gap G. In a non-limiting example, the thickness D9 is greater than 0.01 mm. In a non-limiting example, the thickness D10 is greater than 0.01 mm.

The cover 1302 and the cover ring 1304 of the holding module 1300 independently may be fabricated by machining and welding plates of stainless steel or by machining a single mass of aluminum. However, the disclosure is not limited thereto, alternatively, the cover 1302 include or are plated with aluminum and the cover ring 1304 includes or is plated with stainless steel, or vice versa. In some embodiments, the cover ring 1304 is referred to as a clamp ring or a ring structure, and the holding module 1300 may be referred to as a clamp assembly.

Back to FIG. 1, in some embodiments, the adaptor 1500 is installed onto the sidewalls 1102 of the chamber 1100 and is configured to help the installation of the shield 1600, where the shield 1600 is removably installed onto the adaptor 1500. In some embodiments, the shield 1600 covers the sidewalls 1102 of the chamber 1100 and surrounds the holding module 1300 and the lift assembly 1400, where the shield 1600, and the holding module 1300, the lift assembly 1400 and the upper process assembly 1000 together confine a processing region 1800 (or referred to as a plasma zone) inside the enclosure space ES of the apparatus 10. The shield 1600 helps to reduce deposition of sputtering deposits originating from the target (e.g., 2400) onto the components and surfaces behind (e.g., opposite to the target) the shield 160. The shield 1600 may be made of a dielectric material or a metal, with a high temperature resistant property. As shown in FIG. 1, the shield 1600 may be free from the holding module 1300 and the lift assembly 1400. In other words, there are slits (or gaps) between the shield 1600 and the holding module 1300 and between the shield 1600 and the lift assembly 1400. In some embodiments, the insulator 1700 is disposed on the adapter 1500, where the adapter 1500 is disposed between the insulator 1700 and the sidewalls 1102 of the chamber 1200, and is configured to help the installation of the upper process assembly 2000 onto the lower process assembly 1000. The insulator 1700 is made of a dielectric material, which helps to isolate (e.g., electrically) the adapter 1500 from the components of the upper process assembly 2000.

As illustrated in FIG. 1, in some embodiments, the upper process assembly 2000 includes a target holding plate 2100, an O-ring 2200, a cap 2300, and the target 2400. For example, the upper process assembly 2000 is installed onto the lower process assembly 1000 by fixing the target holding plate 2100 (e.g., a peripherical region thereof) onto the insulator 1700 through a fastener(s) (e.g., blots or blots threaded with nuts, with or without washer). In some embodiments, the target holding plate 2100 has a surface S2100u and a surface S2100l opposite to the surface S2100u, and the surface S2100l of the target holding plate 2100 is connected to (e.g., in physical contact with) the insulator 1700, where the O-ring 2200 is disposed inside the target holding plate 2100 and exposed from the surface S2100l of the target holding plate 2100, which helps to enhance the sealing degrees between the upper process assembly 2000 and the lower process assembly 1000, such as limiting the vacuum leakage therebetween. For example, as the upper process assembly 2000 is installed onto the lower process assembly 1000, the O-ring 2200 is also directly pressed onto the insulator 1700 to secure the sealing degrees between the upper process assembly 2000 and the lower process assembly 1000. In some embodiments, the target holding plate 2100 may be made of a conductive material with sufficient strength to hold the target 2400. The cap 2300 is removably disposed on the surface S2100u of the target holding plate 2100, which helps to protect the components underneath thereto In some embodiments, the cap 2300 may be made of a dielectric material, a conductive material or a combination thereof. For example, the cap 2300 may be a plastic cap or a plastic transparent cap.

In some embodiments, the target 2400 is placed onto the surface S2100l of the target holding plate 2100 and is accessibly exposed to the processing region 1800, where the target 2400 is at least vertically overlapped with the substrate 20 accessibly revealing by the opening OP formed in the holding module 1300 (e.g., the cap 13042), as shown in FIG. 1. For example, the target 2400 is electrically coupled to a DC power system 1930, where the target 2400 is biased to a negative DC bias in the range of about −400 VDC to −600 VDC to attract positive ions of the process gas (e.g., argon) toward the target to sputter the metal atoms; and on the other hand, the shield 1600 and the holding module 1300 are electrically grounded and thus provides an anode in opposition to the target 2400 serving as a cathode so to capacitively couple the DC power into the apparatus 10 and its plasma. For example, a material of the target 2400 include a metal or metal alloy, such as but not limited to aluminum, copper, nickel, platinum, hafnium, silver, chrome, gold, molybdenum, ruthenium, tantalum, titanium, tungsten, lanthanum, nickel platinum alloys, and/or combination thereof. The disclosure is not limited thereto.

In some embodiments, the apparatus 10 is controlled by a controller 1940 that facilitates the control and automation of the apparatus 10 and includes a central processing unit (CPU), a memory unit, and support circuits (or I/O). The CPU may be one of any form of computer processors that are used in industrial settings for controlling various system functions, substrate movement, chamber processes, and support hardware (e.g., sensors, robots, motors, etc.), and monitor the processes (e.g., stage and/or holding module temperature, power supply variables, chamber process time, I/O signals, etc.). The memory unit is connected to the CPU, and may be one or more of a readily available memory, such as random access memory (RAM), read only memory (ROM), floppy disk, hard disk, or any other form of digital storage, local or remote. Software instructions and data can be coded and stored within the memory unit for instructing the CPU. The support circuits are also connected to the CPU for supporting the processor in a conventional manner. The support circuits include cache, power supplies, clock circuits, input/output circuitry, subsystems, and the like. A program (or computer instructions) readable by the controller 1940 determines which tasks to be performed on the substrate. The program is software readable by the controller 1940 that includes code to perform tasks relating to monitoring, execution and control of the movement and various process recipe tasks and recipe steps being performed in the apparatus 10. For example, the controller 1940 includes program code that includes a substrate positioning instruction set to operate the pedestal assembly 1200, the holding module 1300 and the lift assembly 1400, a gas flow control instruction set to operate gas flow control valves to set a flow of sputtering gas to the apparatus 10 (e.g., to operate the gas source(s), such as 1910), a gas pressure control instruction set to operate a throttle valve or gate valve to maintain a pressure in the apparatus 10 (e.g., to operate exhaust pump(s), such as 1920), a voltage control instruction set to operate DC power system 1930, a temperature control instruction set to control a temperature control system in the pedestal assembly 1200 and/or the holding module 1300 to set temperatures of the substrate 20, respectively, and a process monitoring instruction set to monitor the process in the apparatus 10. In other words, the apparatus 10 further includes the gas source 1910, the exhaust pump 1920, the DC power system 1930 and the controller 1940, where the controller 1940 is electrically coupled to the gas source 1910, the exhaust pump 1920, and the DC power system 1930. Although there is only one gas source 1910, one exhaust pump 1920, and one DC power system 1930 depicted in FIG. 1 for illustrative purposes, the number of each of the gas source 1910, the exhaust pump 1920, and the DC power system 1930 independently includes one, two or more, depending on the demand. The disclosure is not specified limited thereto.

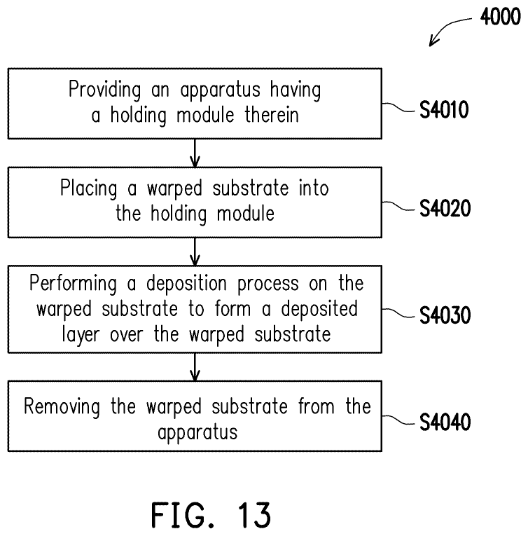

FIG. 13 is a flowchart of a method (e.g., 4000) for using an apparatus (e.g., 10) in accordance with some embodiments of the disclosure. It is understood that additional processes may be provided before, during, and after the illustrated method, and that some other processes may only be briefly described herein. The elements similar to or substantially the same as the elements described previously will use the same reference numbers, and certain details or descriptions (e.g. the materials, positioning configurations, electrical connection relationships, etc.) of the same elements would not be repeated herein. Referring to FIG. 13, in some embodiments, the method 400 of FIG. 13 includes at least steps S4010 to S4040. For example, the method 4000 shown in FIG. 13 beings with step S4010, which provides an apparatus 10 including a holding module 100; step S4020, which places a warped substrate into the holding module; step S4030, which performs a deposition process on the warped substrate to form a deposited layer over the warped substrate; and step S4040, which removes the warped substrate from the apparatus. The details of the apparatus (e.g., 10) and the holding module (e.g., 1300) have previously discussed in FIG. 1 through FIG. 12, and thus are not repeated herein for brevity. In some embodiments, the warped substrate (e.g., 20) is placed into the holding module (e.g., 1300) of the apparatus (e.g., 10) by, but not limited to, raising the supporting structure (e.g., 1402) to the opening position (that the cover ring (e.g., 1304) is lifted up from and spacing apart from the surface (e.g., S13026u) of the horizontal extending portion (e.g., 13026) of the cover (e.g., 1302) by the supporting structure (e.g., 1402) of the lift mechanism (e.g., 1400)) and lowering the stage (e.g., 1202) to the lower transfer position (that the stage (e.g., 1202) is lowered downward from and spacing apart from the target (e.g., 2400) by the lift mechanism (e.g., 1206)), which allows transferring the substrate into the holding module (e.g., 1300) of the apparatus (e.g., 10).

In some embodiments, the deposition process is a PVD process. For example, during a PVD process a target (e.g., 2400) is electrically biased so that ions generated in a process region (e.g., 1800) can bombard a surface of the target (e.g., 2400) accessibly exposed to the process region (e.g., 1800) with sufficient energy to dislodged atoms from the target (e.g., 2400). The process of biasing the target (e.g., 2400) to cause the generation of a plasma that causes ions to bombard and remove atoms from the surface of the target (e.g., 2400) is so-called sputtering. The sputtered atoms travel generally ballistically toward the substrate (e.g., 20 being accessibly exposed by the opening (e.g., OP) formed in the holding module (e.g., 1300)) being sputter coated, and the sputtered atoms are deposited on the substrate (e.g., 20). Alternatively, the atoms react with another gas in the plasma, for example, an oxygen−containing gas, a nitrogen−containing gas, a methane-containing gas or fluorine-containing gas, to reactively deposit a compound on the substrate (e.g., 20). In some embodiments, during the PVD process, the supporting structure (e.g., 1402) is at the enclosing position (that the cover ring (e.g., 1304) is lowered downward from and in contact with the surface (e.g., S13026u) of the horizontal extending portion (e.g., 13026) of the cover (e.g., 1302) by the supporting structure (e.g., 1402) of the lift mechanism (e.g., 1400)) and the stage (e.g., 1202) is at the upper transfer position (that the stage (e.g., 1202) is lifted up and closer to the target (e.g., 2400) by the lift mechanism (e.g., 1206)), which allows maintains and retains the location of the substrate (e.g., 20) during the processing.

In some embodiment, the warped substrate (e.g., 20) is removed from the holding module (e.g., 1300) of the apparatus (e.g., 10) by, but not limited to, raising the supporting structure (e.g., 1402) to the opening position (that the cover ring (e.g., 1304) is lifted up from and spacing apart from the surface (e.g., S13026u) of the horizontal extending portion (e.g., 13026) of the cover (e.g., 1302) by the supporting structure (e.g., 1402) of the lift mechanism (e.g., 1400)) and lowering the stage (e.g., 1202) to the lower transfer position (that the stage (e.g., 1202) is lowered downward from and spacing apart from the target (e.g., 2400) by the lift mechanism (e.g., 1206)), which allows transferring the substrate out of the holding module (e.g., 1300) of the apparatus (e.g., 10).

In accordance with some embodiments, a holding module of a substrate includes a cover and a ring structure. The cover includes a body portion having a step-form profile and a horizontal extending portion connecting to an edge of the body portion. The ring structure is removably installed to the horizontal extending portion, and includes a supporting structure and a cap. The supporting structure stands on the horizontal extending portion. The cap is disposed on the supporting structure, where the supporting structure is disposed between the cover and the cap. The cover and ring structure constitute an accommodating space for the substrate, and the substrate is laid on the body portion and is free from the ring structure.

In accordance with some embodiments, an apparatus for processing a semiconductor wafer includes a target, a pedestal, and a holding module. The pedestal is disposed underneath the target. The holding module is disposed between the pedestal and the target, and includes a cover and a ring structure. The cover includes a body portion having a step-form profile, a vertical extending portion connecting to a bottom of the body portion and further extending onto a sidewall of the pedestal, and a horizontal extending portion connecting to an edge of the body portion and an outer edge of the vertical extending portion. The ring structure is removably installed to the horizontal extending portion, and includes a first supporting structure standing on the horizontal extending portion and a cap disposed on the first supporting structure and having an opening penetrating therethrough, where the first supporting structure is disposed between the cover and the cap. An accommodating space inside the holding module is configured to retain the semiconductor wafer, and the semiconductor wafer is accessibly exposed by the opening and is further overlapped with the target.

In accordance with some embodiments, a method includes the following steps: providing an apparatus, the apparatus comprising a target, a pedestal disposed underneath the target and a holding module disposed between the pedestal and the target and comprising a cover and a ring structure, wherein the cover comprises a body portion having a step-form profile, a vertical extending portion connecting to a bottom of the body portion and further extending onto a sidewall of the pedestal and a horizontal extending portion connecting to an edge of the body portion and an outer edge of the vertical extending portion, and wherein the ring structure is removably installed to the horizontal extending portion and comprises a first supporting structure standing on the horizontal extending portion, and a cap disposed on the first supporting structure and having an opening penetrating therethrough, wherein the first supporting structure is disposed between the cover and the cap; placing a substrate into the holding module, wherein the substrate is accessibly exposed by the opening and overlapped with the target; performing a deposition process on the substrate to form a deposited layer over the substrate; and removing the substrate from the apparatus.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure.

What is claimed is:

1. A holding module of a substrate, comprising:
a cover, comprising:
a body portion having a step-form profile; and
a horizontal extending portion, connecting to an edge of the body portion; and
a ring structure, removably installed to the horizontal extending portion, and comprising:
a supporting structure, standing on the horizontal extending portion; and
a cap, disposed on the supporting structure, wherein the supporting structure is disposed between the cover and the cap,
wherein the cover and ring structure constitute an accommodating space for the substrate, and the substrate is laid on the body portion and is free from the ring structure.

2. The holding module of claim 1, wherein an opening is formed in the cap and vertically overlapped with the substrate, and the substrate is accessibly revealed by the opening.

3. The holding module of claim 1, wherein a step number of the step-form profile is greater than one or more.

4. The holding module of claim 1, wherein the body portion comprises a first region and a second region surrounding and coupled to the first region, a thickness of the first region is less than a thickness of the second region.

5. The holding module of claim 4, wherein a width of the second region is less than a half of a width of the first region.

6. The holding module of claim 4, wherein the body portion further comprises a third region surrounding and coupled to the second region, and the second region separates the first region from the third region,
wherein the thickness of the first region and the thickness of the second region are less than a thickness of the third region,
wherein a width of the second region and a width of the third region are less than a half of a width of the first region, and the width of the third region is less than the width of the second region.

7. The holding module of claim 1, wherein a distance between the substrate and the ring structure is non-zero.

8. An apparatus for processing a semiconductor wafer, comprising:
a target;
a pedestal, disposed underneath the target; and
a holding module, disposed between the pedestal and the target, and comprising:
a cover, comprising:
a body portion having a step-form profile;
a vertical extending portion, connecting to a bottom of the body portion and further extending onto a sidewall of the pedestal; and
a horizontal extending portion, connecting to an edge of the body portion and an outer edge of the vertical extending portion; and
a ring structure, removably installed to the horizontal extending portion, and comprising:
a first supporting structure, standing on the horizontal extending portion; and
a cap, disposed on the first supporting structure and having an opening penetrating therethrough, wherein the first supporting structure is disposed between the cover and the cap,
wherein an accommodating space inside the holding module is configured to retain the semiconductor wafer, and the semiconductor wafer is accessibly exposed by the opening and is further overlapped with the target.

9. The apparatus of claim 8, further comprising:
a housing, having a bottom and sidewalls connecting to edges of the bottom, wherein the pedestal is installed on the bottom of the housing, and the pedestal is disposed between the holding module and the bottom of the housing;
a target holding plate, disposed on the sidewalls of the housing, wherein the target is installed on the target holding plate, and the target is disposed between the target holding plate and the holding module; and
a shield, removably installed on the sidewalls of the housing through an adapter, wherein the shield covers the sidewalls of the housing and surrounds the holding module, and a process region is confined by the shield, the holding module and the target holding plate.

10. The apparatus of claim 9, wherein the shield is electrically grounded, and the apparatus further comprises
at least one DC power system, wherein one of the at least one DC power system is electrically coupled to the target to provide voltage bias thereon;
at least one gas source, coupled to the housing and is configured to provide a process gas;
at last one exhaust pump, coupled to the housing and is configured to exhaust a spent process gas and a byproduct; and
a controller, electrically coupled to the at least one DC power system, the at least one gas source and the at least one exhaust pump and is configured to control the processing the semiconductor wafer.

11. The apparatus of claim 9, further comprising:
an insulator, disposed on the adapter and is configured in contact with the target holding plate, wherein the adapter is posited between the sidewalls of the housing and the insulator, and the insulator is posited between the adapter and the target holding plate to electrically isolated the target holding plate from the housing and the adaptor.

12. The apparatus of claim 8, further comprising:
a lift assembly, coupled to the ring structure and is configurated to raise or lower the ring structure in relative to a position of the cover for transporting of the semiconductor wafer in and out of the holding module,
wherein the ring structure further comprises a second supporting structure laterally surrounding the first supporting structure by a gap, the cap is further outwardly extended on to the second supporting structure, and a supporting structure of the lift assembly is inserted into the gap and props against the cap so to support the ring structure.

13. The apparatus of claim 8, wherein the body portion comprises a central region and one or more annular regions surrounding the central region,
wherein in a plane view of the body portion, each of the central region and the one or more annular regions has a lateral width, and the lateral widths of the central region and the one or more annular regions are decreased from a center of the body portion toward to the edge of the body portion.

14. The apparatus of claim 13, wherein in a cross-section of the body portion, each of the central region and the one or more annular regions has a thickness, and the thickness es of the central region and the one or more annular regions are increased from the center of the body portion toward to the edge of the body portion.

15. The apparatus of claim 8, wherein in a plane view of the body portion, the step-form profile of the body portion is a point symmetric.

16. The apparatus of claim 8, wherein in a cross-section of the body portion, the step-form profile of the body portion is a point symmetric.

17. A method, comprising:
providing an apparatus, the apparatus comprising a target, a pedestal disposed underneath the target and a holding module disposed between the pedestal and the target and comprising a cover and a ring structure, wherein the cover comprises a body portion having a step-form profile, a vertical extending portion connecting to a bottom of the body portion and further extending onto a sidewall of the pedestal and a horizontal extending portion connecting to an edge of the body portion and an outer edge of the vertical extending portion, and wherein the ring structure is removably installed to the horizontal extending portion and comprises a first supporting structure standing on the horizontal extending portion, and a cap disposed on the first supporting structure and having an opening penetrating therethrough, wherein the first supporting structure is disposed between the cover and the cap;
placing a substrate into the holding module, wherein the substrate is accessibly exposed by the opening and overlapped with the target;
performing a deposition process on the substrate to form a deposited layer over the substrate; and
removing the substrate from the apparatus.

18. The method of claim 17, wherein the performing the deposition process comprises performing a PVD process.

19. The method of claim 17, wherein the body portion comprises a central region and one or more annular regions surrounding the central region,
wherein in a plane view of the body portion, each of the central region and the one or more annular regions has a lateral width, and the lateral widths of the central region and the one or more annular regions are decreased from a center of the body portion toward to the edge of the body portion, and
wherein in a cross-section of the body portion, each of the central region and the one or more annular regions has a thickness, and the thickness es of the central region and the one or more annular regions are increased from the center of the body portion toward to the edge of the body portion.

20. The method of claim 17, wherein the step-form profile of the body portion matches a warpage of the substrate after placing the substrate into the holding module.
